(19) United States
(12) Patent Application Publication
(10) Pub. No.: US 2026/0157068 A1
(43) Pub. Date: Jun. 4, 2026

(54) DISPLAY PANEL AND ELECTRONIC DEVICE

(71) Applicants: Hefei Visionox Technology Co., Ltd., Hefei (CN); Hefei Visionox Electronics Co., Ltd., Hefei (CN); Visionox Technology Inc., Kunshan (CN)

(72) Inventors: Zhiwei ZHOU, Hefei (CN); Tian WANG, Hefei (CN); Jinfang ZHANG, Hefei (CN); Guodong LIU, Hefei (CN); Meng ZHANG, Kunshan (CN)

(73) Assignees: Hefei Visionox Technology Co., Ltd., Hefei (CN); Hefei Visionox Electronics Co., Ltd., Hefei (CN); Visionox Technology Inc., Kunshan (CN)

(21) Appl. No.: 19/300,595

(22) Filed: Aug. 14, 2025

(30) Foreign Application Priority Data
Nov. 29, 2024 (CN) 202411747265.8

(51) Int. Cl. H10K 59/35; H10K 59/122; H10K 59/131; H10K 59/80

(52) U.S. Cl. CPC H10K 59/353; H10K 59/122; H10K 59/131; H10K 59/873

(57) ABSTRACT

The present application provides a display panel and an electronic device. The display panel includes: a substrate; an array functional layer on one side of the substrate; and a plurality of light-emitting devices located on a side of the array functional layer away from the substrate and spaced apart from each other, each of the light-emitting devices including a first electrode, a light-emitting layer and a second electrode which are stacked in a direction away from the substrate; where the array functional layer includes a routing hole; and the first electrode includes a connecting portion, the connecting portion extending into the routing hole and being electrically connected to a pixel drive circuit in the array functional layer. An orthographic projection of the connecting portion on the substrate is close to an orthographic projection of a first side of the first electrode on the substrate.

### CROSS-REFERENCE TO RELATED APPLICATIONS

The present application claims priority to the Chinese Patent Application No. 202411747265.8, filed on Nov. 29, 2024, and the entire contents of the aforementioned application are hereby incorporated by reference in its entirety.

### FIELD

The present application relates to the field of display, and particularly to a display panel and an electronic device.

### BACKGROUND

Organic light-emitting diodes (OLEDs) and flat panel display devices based on technologies such as light-emitting diodes (LEDs) have been widely applied to various consumer electronics such as mobile phones, televisions, notebook computers and desktop computers and predominate in display devices thanks to their advantages such as high image quality, energy efficiency, slim design and a wide range of applications.

However, the performance of conventional OLED display products needs to be improved.

### SUMMARY

In order to overcome the above-mentioned disadvantages of the prior art, an objective of the present application is to provide a display panel, including:
a substrate;
an array functional layer on one side of the substrate; and
a plurality of light-emitting devices located on a side of the array functional layer away from the substrate and spaced apart from each other, each of the light-emitting devices including a first electrode, a light-emitting layer and a second electrode which are stacked in a direction away from the substrate;
where the array functional layer includes a routing hole; the first electrode includes a connecting portion, the connecting portion extending into the routing hole and being electrically connected to a pixel drive circuit in the array functional layer; and An orthographic projection of the connecting portion on the substrate is close to an orthographic projection of a first side of the first electrode on the substrate, and a maximum width of the connecting portion in a direction away from the first side is less than its maximum widths in other directions.

A further objective of the present application is to provide an electronic device, including a display panel provided in the present application.

The present application has the following beneficial effects with respect to the prior art.

The present application provides a display panel and an electronic device. The connecting portion of the first electrode of the light-emitting device is arranged such that the maximum width in the direction away from the first side is less than the maximum width in other directions, as such, it is possible to reduce a spacing between the first electrode and a first electrode of a further light-emitting device in the direction away from the first side while the conductive area of the connecting portion is ensured, thereby improving the pixel opening rate of the display panel.

### BRIEF DESCRIPTION OF THE DRAWINGS

FIG. 1 is a schematic diagram of a display panel in the related art;

FIG. 2 is a first schematic diagram of a display panel according to an embodiment of the present application;

FIG. 3 is a first schematic diagram of a first electrode according to an embodiment of the present application;

FIG. 4 is a second schematic diagram of a first electrode according to an embodiment of the present application;

FIG. 5 is a third schematic diagram of a first electrode according to an embodiment of the present application;

FIG. 6 is a fourth schematic diagram of a first electrode according to an embodiment of the present application;

FIG. 7 is a fifth schematic diagram of a first electrode according to an embodiment of the present application;

FIG. 8 is a sixth schematic diagram of a first electrode according to an embodiment of the present application;

FIG. 9 is a seventh schematic diagram of a first electrode according to an embodiment of the present application;

FIG. 10 is an eighth schematic diagram of a first electrode according to an embodiment of the present application;

FIG. 11 is a ninth schematic diagram of a first electrode according to an embodiment of the present application;

FIG. 12 is a tenth schematic diagram of a first electrode according to an embodiment of the present application;

FIG. 13 is an eleventh schematic diagram of a first electrode according to an embodiment of the present application;

FIG. 14 is a twelfth schematic diagram of a first electrode according to an embodiment of the present application;

FIG. 15 is a thirteenth schematic diagram of a first electrode according to an embodiment of the present application;

FIG. 16 is a second schematic diagram of a display panel according to an embodiment of the present application;

FIG. 17 is a third schematic diagram of a display panel according to an embodiment of the present application;

FIG. 18 is a first schematic diagram of an isolation structure according to an embodiment of the present application; and

FIG. 19 is a second schematic diagram of an isolation structure according to an embodiment of the present application.

List of reference signs: 111—Substrate; 112—Array functional layer; 1121—Pixel drive circuit; 120—First electrode; 1201—Body portion; 1202—Protrusion; 1203 Connecting portion; 1211—First body portion; 1212—First protrusion; 1221—Second body portion; 1222—Second protrusion; 1231—Third body portion; 1232—Third protrusion; 701—First side; 601—First gap; 130—Pixel defining layer; 140—Isolation structure; 150—Light-emitting unit; 160—Second electrode; 170—Encapsulation unit; 180—First encapsulation layer; 190—Second encapsulation layer; 810—Light-emitting device; 811—First light-emitting device; 812—Second light-emitting device; 813—Third light-emitting device; 141—Support portion; 142—Shielding portion; 143—Receiving portion; 910—Isolation opening; 930—Inner recess; 933—First inner recess.

### DETAILED DESCRIPTION OF THE EMBODIMENTS

Patents CN118251982A, 202410864269.8, PCT/CN2024/098407, PCT/CN2024/102783, PCT/CN2024/098217, PCT/CN2024/099419, PCT/CN2024/099072, CN117979755A, CN117998900A, CN117062489A, CN117580403A, CN116583155A, CN116669477A, CN117396039A, CN116669480A, CN116600606A, and CN117500332A describe related embodiments for an isolation structure, the contents of which are incorporated herein by reference.

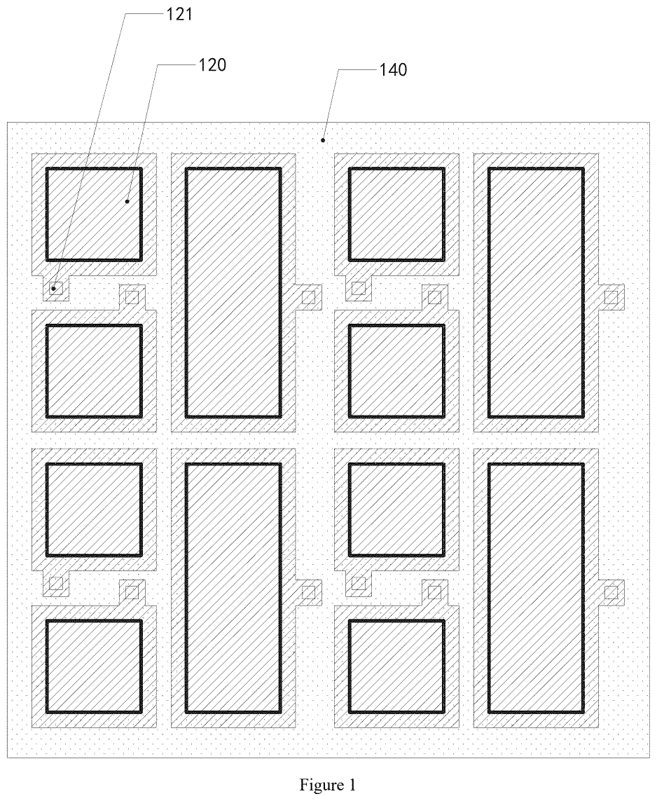

With reference to FIG. 1, in a display panel of some related technologies, the display panel typically includes an array functional layer 112 and light-emitting devices 810 disposed on the array functional layer 112, each of the light-emitting devices 810 including a first electrode 120, a light-emitting functional layer and a second electrode 160. The first electrode 120 generally needs to extend through a routing hole to a pixel drive circuit 1121 in the array functional layer 112.

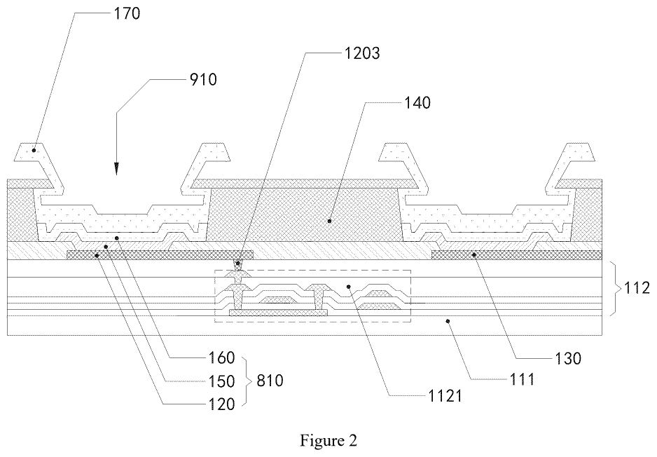

With reference to FIG. 2, in order to prevent the routing hole from affecting the light-emitting effect, the position of the routing hole generally does not overlap with the position of a light-emitting area, and in this case, it is often necessary to place the routing hole in a gap between adjacent light-emitting devices 810. In order to ensure that the first electrode 120 that extends into the routing hole has a sufficient conductive area, the routing hole needs to have a sufficient width, causing a difficulty in reducing a spacing between pixels, which affects a pixel opening rate of the display panel.

In view of this, this embodiment provides a solution by which the pixel opening rate of the display panel can be improved, and the solution provided in this embodiment will be elaborated below.

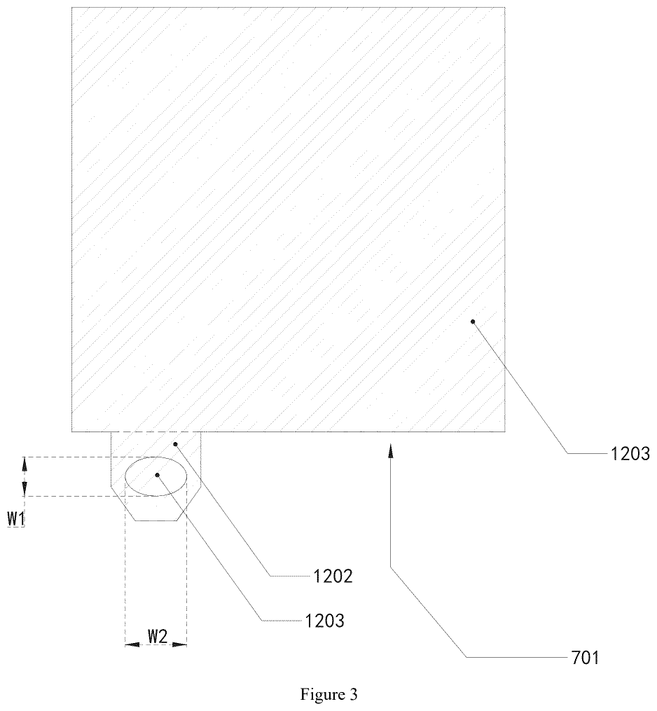

With reference to FIGS. 2 and 3, the present application provides a display panel, including a substrate 111, an array functional layer 112, and light-emitting devices 810.

In this embodiment, a material of the substrate 111 may include a rigid material, such as glass. In one embodiment, the material of the substrate 111 may include a flexible material, such as polyimide (Pi).

The array functional layer 112 is located on one side of the substrate 111, and the array functional layer 112 may include a plurality of film layer structures, such as a buffer layer, an active layer, a plurality of conductive layers, a plurality of insulation layers, a planarization layer, etc. The plurality of film layer structures of the array functional layer 112 can form a plurality of thin film transistors (TFTs) at different locations, and the thin film transistors cooperate with each other to form a plurality of pixel drive circuits 1121. The conductive layers of the array functional layer 112 may also form a trace that is connected to a pixel drive power supply.

A plurality of light-emitting devices 810 are located on a side of the array functional layer 112 away from the substrate 111 and are spaced apart from each other. Each of the light-emitting devices 810 includes a first electrode 120, a light-emitting layer and a second electrode 160 which are stacked in a direction away from the substrate 111.

In this embodiment, the array functional layer 112 includes a routing hole, and the first electrode 120 includes a connecting portion 1203, the connecting portion 1203 extending into the routing hole and being electrically connected to the pixel drive circuit 1121 in the array functional layer 112.

An orthographic projection of the connecting portion 1203 on the substrate 111 is close to an orthographic projection of a first side 701 of the first electrode 120 on the substrate 111, and a maximum width of the connecting portion 1203 in a direction away from the first side 701 is less than its maximum widths in other directions.

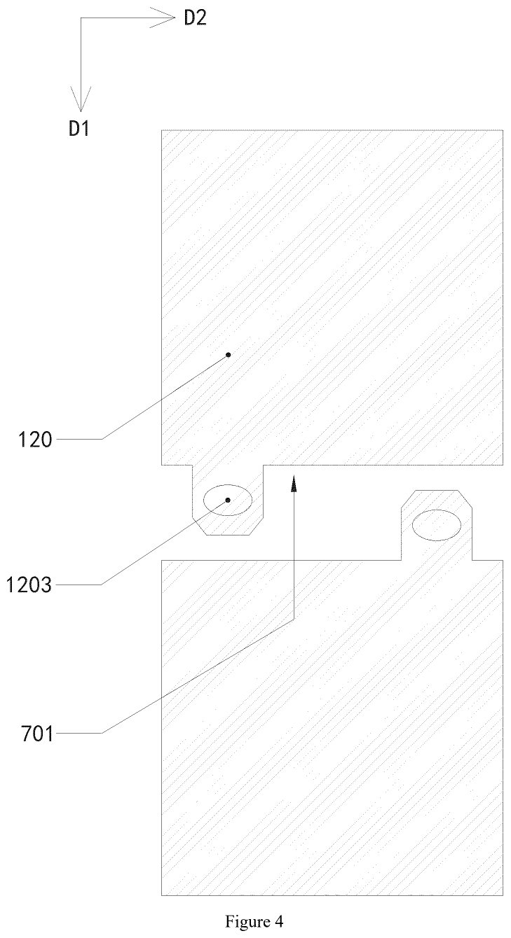

Based on the above design, the connecting portion 1203 of the first electrode 120 of the light-emitting device 810 is arranged such that the maximum width in the direction away from the first side 701 is less than the maximum widths in other directions, as such, with reference to FIG. 4, it is possible to reduce a spacing between the first electrode 120 and a first electrode 120 of a further light-emitting device 810 in the direction away from the first side 701 while the conductive area of the connecting portion 1203 is ensured, thereby improving the pixel opening rate of the display panel.

In some embodiments, the orthographic projection of the connecting portion 1203 on the substrate 111 is at least one of an ellipse, a diamond and a rectangle, and a major axis of the orthographic projection of the connecting portion 1203 on the substrate 111 is parallel to the first side 701 and has a length W2. A minor axis of the orthographic projection of the connecting portion 1203 on the substrate 111 is perpendicular to the first side 701 and has a length of W1, where W1<W2.

The major axis of the orthographic projection of the connecting portion 1203 on the substrate 111 may be the longest axis of symmetry in the geometry of a geometric shape formed by the major axis of the orthographic projection of the connecting portion 1203 on the substrate 111.

In one embodiment, the orthographic projection of the connecting portion 1203 on the substrate 111 is elliptical, and the etching difficulty of the routing hole and the manufacturing difficulty of the connecting portion 1203 may be reduced.

In one embodiment, the length W1 of the minor axis of the orthographic projection of the connecting portion 1203 on the substrate 111 is 2.5 microns to 4 microns, which may be 2.8 microns, 3 microns, 3.5 microns, 3.8 microns, for example.

In other embodiments, the orthographic projection of the connecting portion 1203 on the substrate 111 may also be of other shapes. For example, the orthographic projection of the connecting portion 1203 on the substrate 111 is rectangular, a long side of the orthographic projection of the connecting portion 1203 on the substrate 111 is parallel to the first side 701, and a short side of the orthographic projection of the connecting portion 1203 on the substrate 111 is perpendicular to the first side 701.

In some embodiments, with reference to FIG. 2, the display panel also includes an isolation structure 140, the isolation structure 140 being located on one side of the substrate 111, and the isolation structure 140 enclosing an isolation opening 910. An orthographic projection of the isolation opening 910 on the substrate 111 is located within an orthographic projection of the first electrode 120 on the substrate 111, the isolation opening 910 exposes at least part of the first electrode 120 of the light-emitting device 810, and at least part of the light-emitting layer and the second electrode 160 of the light-emitting device 810 is located within the isolation opening 910.

The orthographic projection of the isolation opening 910 on the substrate 111 is staggered with the orthographic projection of the connecting portion 1203 on the substrate 111. In this way, the light-emitting functional layer of the light-emitting device 810 can be prevented from falling into the routing hole, affecting the light-emitting effect.

In some embodiments, referring again to FIG. 3, the first electrode 120 of at least part of the light-emitting devices 810 includes a body portion 1201 and a protrusion 1202, and the protrusion 1202 protrudes from a side of the body portion 1201 close to a further light-emitting device 810 in a direction away from the body portion 1201. The orthographic projection of the connecting portion 1203 on the substrate 111 is located within an orthographic projection of the protrusion 1202 on the substrate 111.

In this case, the first side 701 may be a side of the body portion 1201 close to the side of the protrusion 1202. As such, the maximum width of the connecting portion 1203 in the direction away from the first side 701 is less than the maximum width in other directions, and the width of the protrusion 1202 in the direction away from the first side 701 can be reduced, thereby reducing the spacing between the light-emitting devices 801, and increasing the pixel opening rate of the display panel.

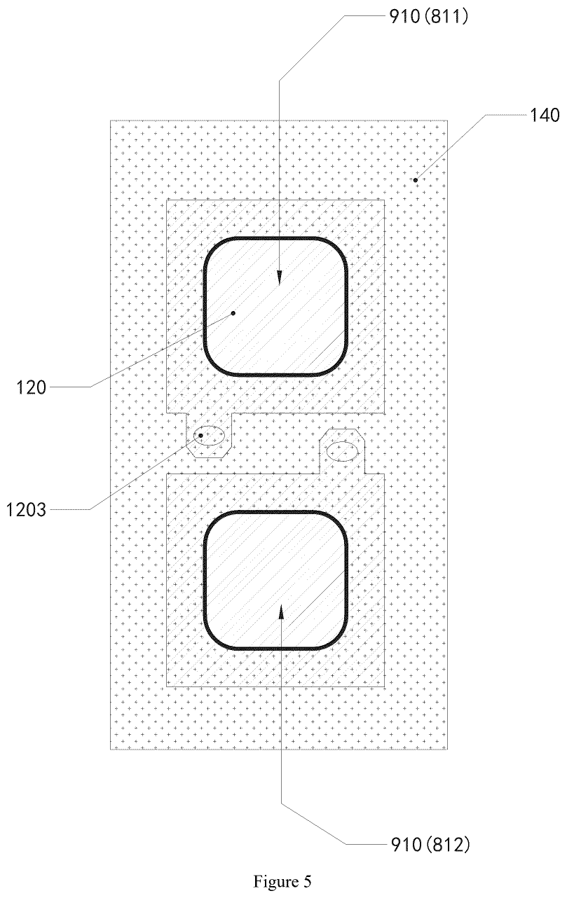

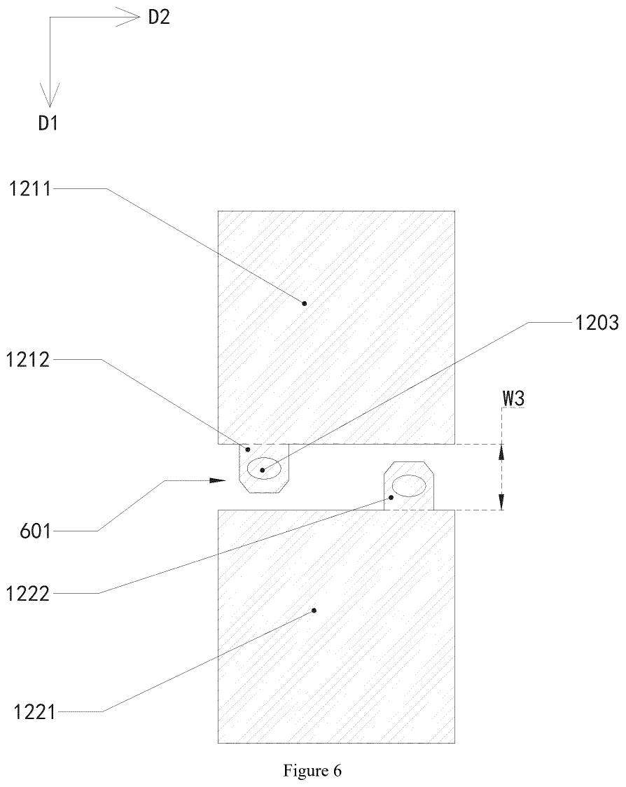

In some embodiments, with reference to FIGS. 5 and 6, the light-emitting device 810 includes a first light-emitting device 811 and a second light-emitting device 812 that are adjacent to each other. In one embodiment, light-emitting colors of the first light-emitting device 811 and the second light-emitting device 812 may be different. For example, a material of a light-emitting layer 150 of the first light-emitting device 811 may be different from a material of a light-emitting layer 150 of the second light-emitting device 812.

The first electrode 120 of the first light-emitting device 811 includes a first body portion 1211 and a first protrusion 1212, the first protrusion 1212 protruding from a side of the first body portion 1211 close to the second light-emitting device 812 toward the second light-emitting device 812. An orthographic projection of the connecting portion 1203 corresponding to the first light-emitting device 811 on the substrate 111 is located within an orthographic projection of the first protrusion 1212 on the substrate 111.

That is, in this embodiment, by providing the routing hole and the connecting portion 1203 at the position of the first protrusion 1212 outside the first body portion 1211, it is possible to prevent the connecting portion 1203 from affecting the area of the isolation opening 910, thereby increasing the pixel opening rate.

Accordingly, the first electrode 120 of the second light-emitting device 812 includes a second body portion 1221 and a second protrusion 1222, the second protrusion 1222 protruding from a side of the second body portion 1221 close to the first light-emitting device 811 toward the first light-emitting device 811. An orthographic projection of the connecting portion 1203 corresponding to the second light-emitting device 812 on the substrate 111 is located within an orthographic projection of the second protrusion 1222 on the substrate 111.

In some embodiments, a first gap 601 is provided between the first body portion 1211 and the second body portion 1221, and the first protrusion 1212 and the second protrusion 1222 are located in the first gap 601. That is, in this embodiment, the first protrusion 1212 and the second protrusion 1222 share the first gap 601, which may further reduce the area occupied by the first protrusion 1212, and increase the pixel opening rate.

In one embodiment, the first light-emitting device 811 and the second light-emitting device 812 are arranged in a first direction D1, and the first protrusion 1212 and the second protrusion 1222 are staggered in the first direction D1, i.e., in the first direction D1, the first protrusion 1212 and the second protrusion 1222 are in the same straight line. Thus, the first protrusion 1212 and the second protrusion 1222 are disposed in the first gap 601, which may reduce the area occupied by the first protrusion 1212 and the second protrusion 1222, and increase the pixel opening rate.

In one embodiment, in this case, the first gap 601 has a width W3 of 3 to 8 microns.

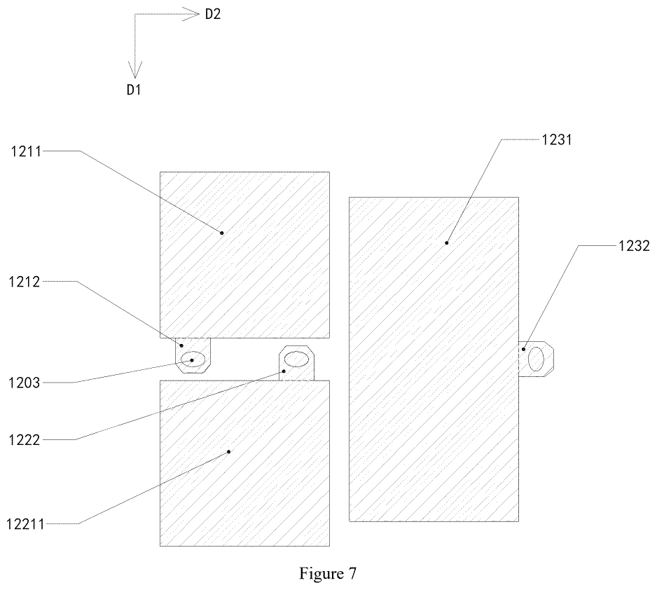

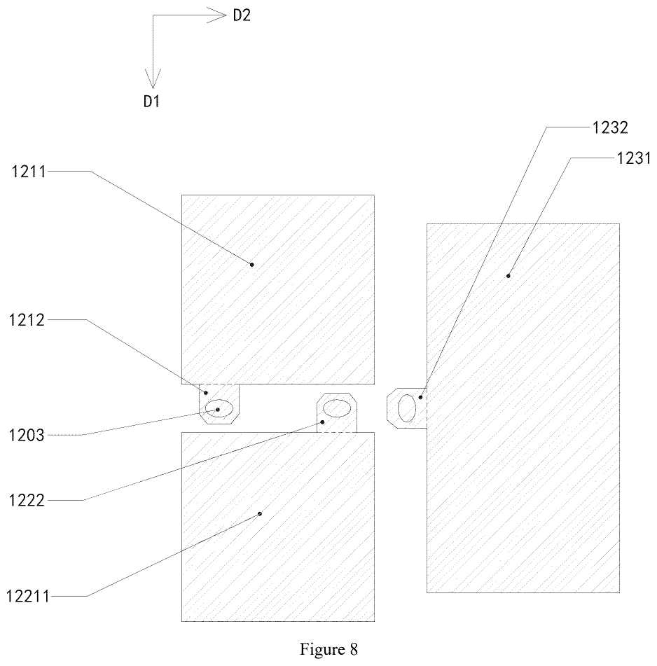

In some embodiments, with reference to FIGS. 7 and 8, the light-emitting device 810 includes a third light-emitting device 813, the third light-emitting device 813 being adjacent to both the first light-emitting device 811 and the second light-emitting device 812. For example, the first light-emitting device 811 and the second light-emitting device 812 are arranged in the first direction D1, and the third light-emitting device 813 is located on a side of the first light-emitting device 811 and the second light-emitting device 812 in a second direction D2, the second direction D2 intersecting the first direction D1, for example, the second direction D2 being perpendicular to the first direction D1.

In one embodiment, light-emitting colors of the first light-emitting device 811, the second light-emitting device 812 and the third light-emitting device 813 are different from each other, for example, the light-emitting colors of the first light-emitting device 811, the second light-emitting device 812 and the third light-emitting device 813 may be one of red, green and blue, respectively.

The first electrode 120 of the third light-emitting device 813 includes a third body portion 1231 and a third protrusion 1232, the third protrusion 1232 protruding in the second direction D2 from the third body portion 1231 in a direction away from said third body portion 1231. An orthographic projection of the connecting portion 1203 corresponding to the third light-emitting device 813 on the substrate 111 is located within an orthographic projection of the third protrusion 1232 on the substrate 111.

In one embodiment, the third protrusion 1232 is located on a side of the third body portion 1231 close to the first light-emitting device 811 and/or the second light-emitting device 812, or the third protrusion 1232 is located on a side of the third body portion 1231 away from the first light-emitting device 811 and/or the second light-emitting device 812.

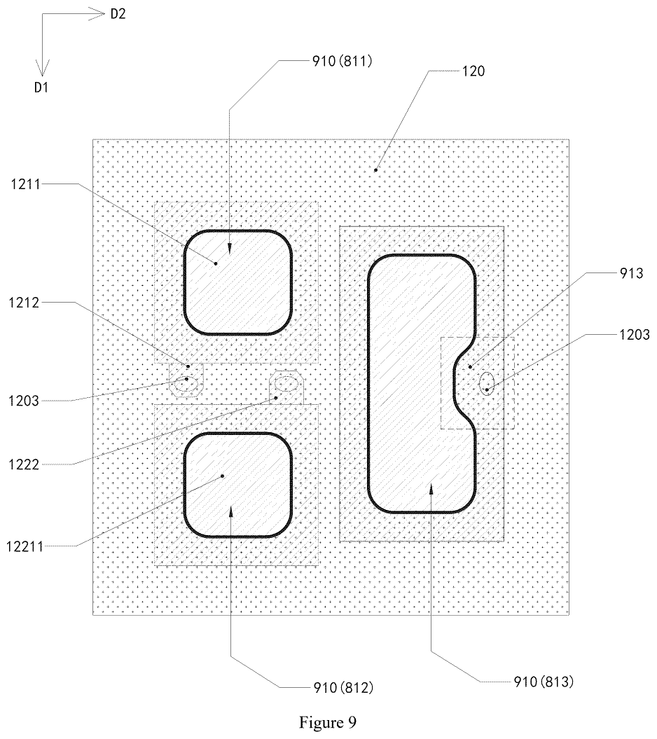

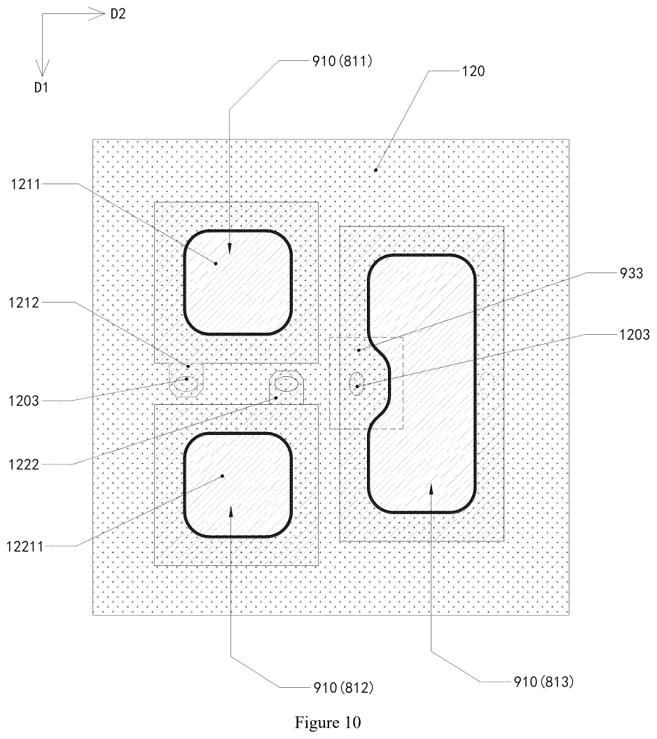

In some embodiments, with reference to FIGS. 9 and 10, the isolation structure 140 corresponding to the third light-emitting device 813 includes a first inner recess 933 (as shown by a dashed box in FIGS. 7 and 8) that protrudes to a center of the isolation opening 910 corresponding to the third light-emitting device 813, and the first inner recess 933 is located on a side of the isolation opening 910 corresponding to the third light-emitting device 813 in the second direction D2.

An orthographic projection of the connecting portion 1203 corresponding to the third light-emitting device 813 on the substrate 111 at least partially coincides with an orthographic projection of the first inner recess 933 on the substrate 111. In this case, the first side 701 of the first electrode 120 of the third light-emitting device 813 is a side close to the first inner recess 933.

The first inner recess 933 is located on a side of the isolation opening 910 corresponding to the third light-emitting device 813 that is close to the first light-emitting device 811 and/or the second light-emitting device 812, or the first inner recess 933 is located on a side of the isolation opening 910 corresponding to the third light-emitting device 813 away from the first light-emitting device 811 and/or the second light-emitting device 812.

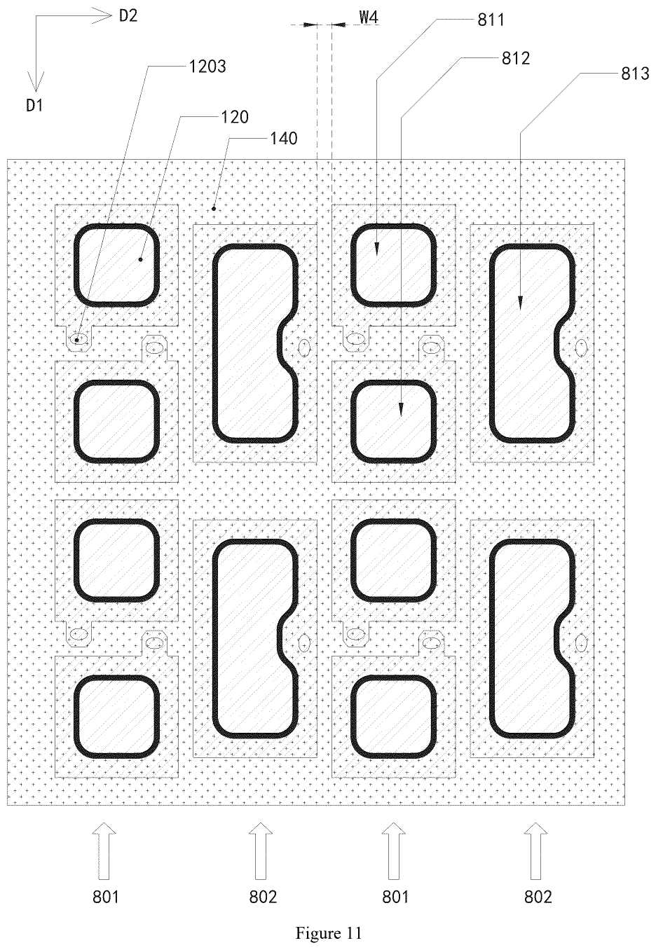

In this case, with reference to FIG. 11, the minimum distance W4 from a side of the first electrode 120 of the third light-emitting device 813 that is provided with the connecting portion 1203 to the other first electrode is 3 to 8 microns, which may be, for example, 4 microns, 5 microns, 6 microns, 7 microns, etc.

As such, the isolation opening 910 corresponding to the third light-emitting device 813 is provided with the first inner recess 933, and the connecting portion 1203 of the first electrode 120 of the third light-emitting device 813 is provided at the first inner recess 933, and the provision of additional protrusions on the first electrode 120 of the third light-emitting device 813 can be avoided, and the spacing between the first electrode 120 of the third light-emitting device 813 and the first electrode 120 of the other light-emitting device 810 is thus reduced, thereby improving the pixel opening rate of the display panel.

Further, in the above embodiments, orthographic projections of the connecting portion 1203 corresponding to the first light-emitting device 811, the connecting portion 1203 corresponding to the second light-emitting device 812 and the connecting portion 1203 corresponding to the third light-emitting device 813 on the substrate are on the same straight line. For example, orthographic projections of the connecting portion 1203 corresponding to the first light-emitting device 811, the connecting portion 1203 corresponding to the second light-emitting device 812 and the connecting portion 1203 corresponding to the third light-emitting device 813 on the substrate are on the same line extending in the second direction D2.

In some embodiments, with reference to FIG. 11, the display panel includes a first pixel column 801 and a second pixel column 802. In the first pixel column 801, a plurality of first light-emitting devices 811 and a plurality of second light-emitting devices 812 are alternately arranged in the first direction D1. In the second pixel column 802, a plurality of third light-emitting devices 813 are arranged in the first direction D1. The first pixel column 801 and the second pixel column 802 are alternately arranged in the second direction D2.

In one embodiment, one of the first light-emitting devices 811 and one of the second light-emitting devices 812 that are adjacent to each other in the same first pixel column 801 form a group, and one of the third light-emitting devices 813 is located on a side of the group of the first light-emitting device 811 and the second light-emitting device 812 in the second direction D2.

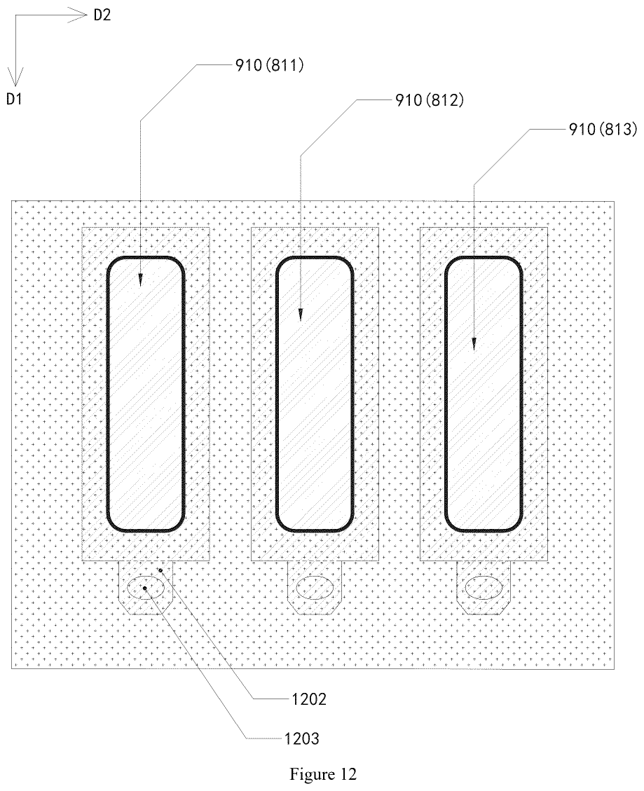

In some other embodiments, with reference to FIG. 12, on the basis of the solution shown in FIG. 3, the light-emitting device 810 includes a first light-emitting device 811, a second light-emitting device 812 and a third light-emitting device 813, the first light-emitting device 811, the second light-emitting device 812 and the third light-emitting device 813 being arranged in the second direction D2. The protrusion 1202 corresponding to each of the light-emitting devices 810 is located on a side of the body portion 1201 in the first direction D1, the first direction D1 intersecting the second direction D2, for example, the first direction D1 being perpendicular to the second direction D2.

In one embodiment, orthographic projections of the connecting portions 1203 corresponding to the light-emitting devices arranged in the second direction D2 on the substrate 111 are on the same straight line.

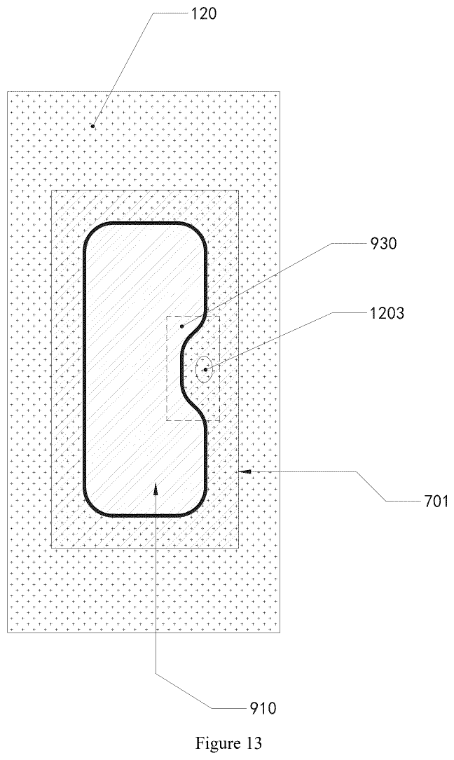

In some embodiments, with reference to FIG. 13, at least part of the isolation structure 140 corresponding to the light emitting device 811 includes an inner recess 930 that protrudes to the center of the corresponding isolation opening 910, the inner recess 930 being located on a side of the isolation opening 910 close to the other isolation opening 910.

An orthographic projection of the connecting portion 1203 corresponding to the light-emitting device 810 on the substrate 111 at least partially coincides with an orthographic projection of the inner recess 930 on the substrate 111. The side of the first electrode 120 close to the inner recess 930 is the first side 701.

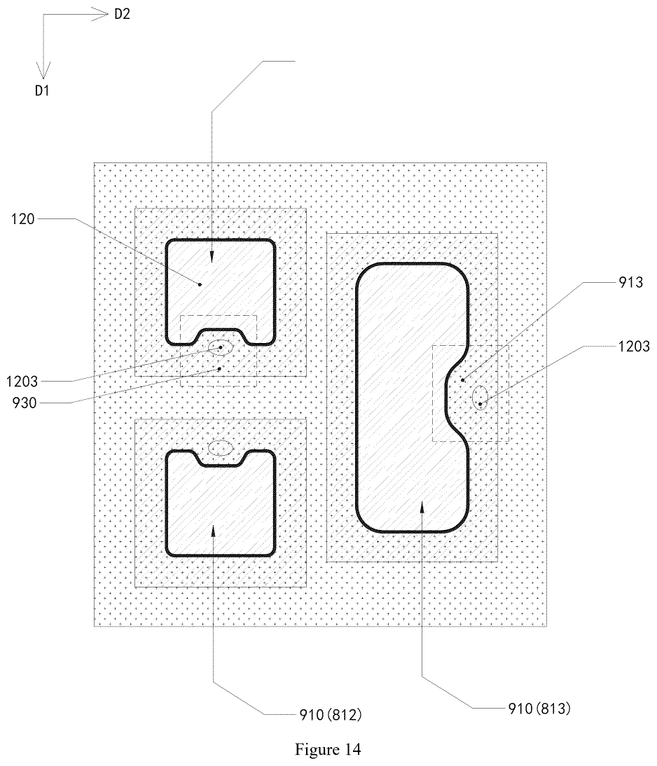

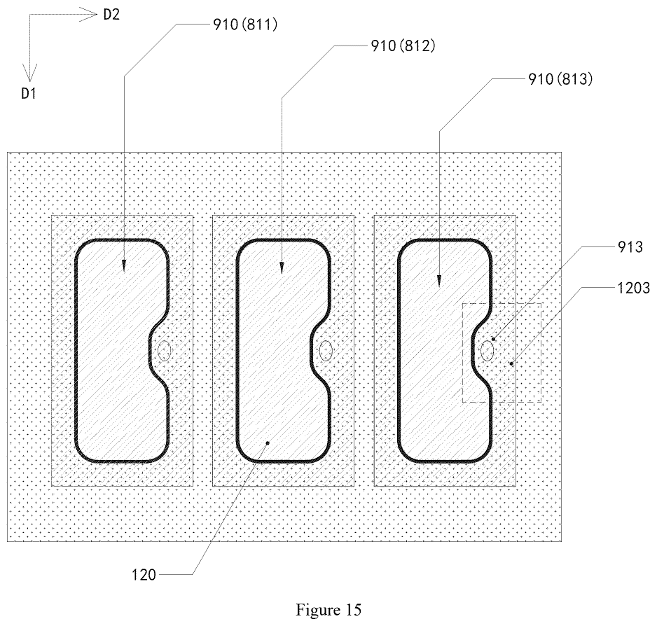

In one embodiment, with reference to FIGS. 14 and 15, on the basis of the solution shown in FIG. 13, the light-emitting device 810 includes a first light-emitting device 811, a second light-emitting device 812, and a third light-emitting device 813, and in the case that the inner recess 930 is located on the side of the isolation opening 910 close to the other isolation opening 910, the first light-emitting device 811, the second light-emitting device 812 and the third light-emitting device 813 may be arranged differently, which is not specifically limited in this embodiment.

In some embodiments, the display panel further includes a pixel defining layer 130 located between the array functional layer 112 and the isolation structure 140, the pixel defining layer 130 including a pixel opening, and an orthographic projection of the pixel opening on the substrate 111 being located within the orthographic projection of the isolation opening 910 on the substrate 111. The pixel opening exposes at least part of the first electrode 120.

In some embodiments, referring to FIG. 2 again, the orthographic projection of the connecting portion 1203 on the substrate 111 may be outside the orthographic projections of the pixel opening and the isolation opening 910 on the substrate 111.

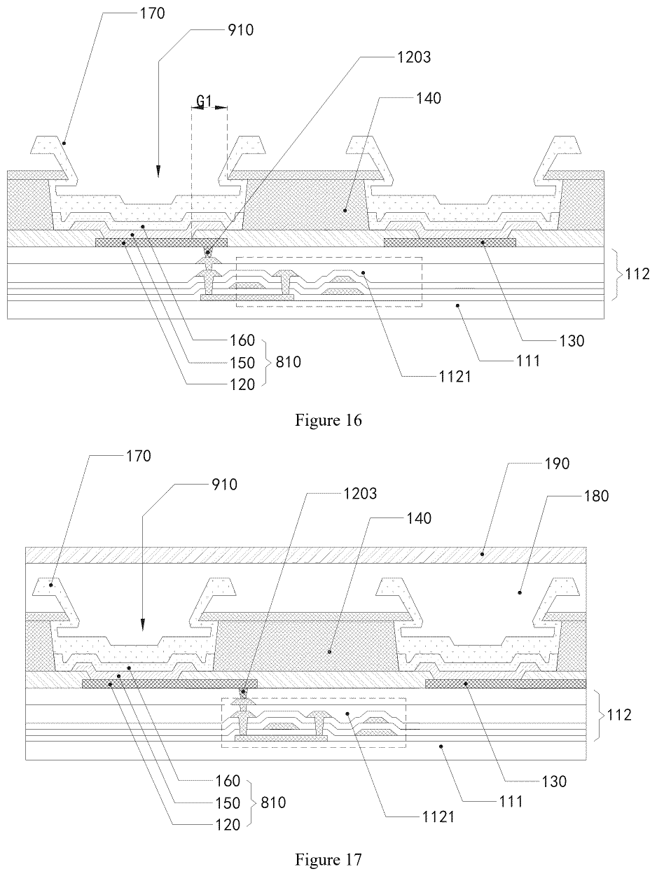

In some other embodiments, with reference to FIG. 16, a first spacing G1 is provided between an edge of an orthographic projection of at least part of the isolation opening 910 corresponding to the light-emitting device 810 on the substrate 111 and an edge of an orthographic projection of the pixel opening corresponding to the light-emitting device 810 on the substrate 111. In addition, the orthographic projection of the connecting portion 1203 corresponding to the light-emitting device 810 on the substrate 111 at least partially coincides with the orthographic projection of the first spacing G1 on the substrate 111.

That is, the orthographic projection of the connecting portion 1203 on the substrate 111 may be located within the orthographic projection of the isolation opening 910 on the substrate 111, but outside the orthographic projection of the pixel opening on the substrate 111.

In one embodiment, on the basis of the solution shown in FIG. 16, the light-emitting device 810 includes a first light-emitting device 811, a second light-emitting device 812, and a third light-emitting device 813, and in the case that the inner recess 930 is located on the side of the isolation opening 910 close to the other isolation opening 910, the first light-emitting device 811, the second light-emitting device 812 and the third light-emitting device 813 may be arranged differently, which is not specifically limited in this embodiment.

In some embodiments, the display panel further includes an encapsulation unit 170 on a side of the second electrode 160 away from the substrate 111, the encapsulation unit 170 extending from within the pixel opening to a side of the isolation structure 140 away from the substrate 111.

In one embodiment, a second gap is provided between at least two adjacent encapsulation units 170, and the second gap is located on the side of the isolation structure 140 away from the substrate 111.

In some embodiments, with reference to FIG. 17, the display panel further includes a first encapsulation layer 180 and a second encapsulation layer 190 on a side of the encapsulation unit 170 and the isolation structure 140 away from the substrate 111.

In one embodiment, a material of each of the encapsulation unit 170 and the second encapsulation layer 190 includes an inorganic material. A material of the first encapsulation layer 180 includes an organic material.

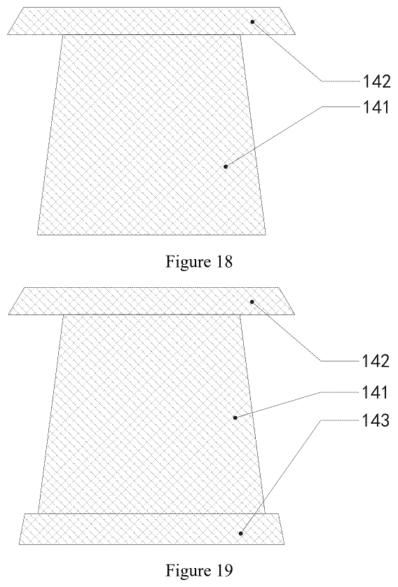

In some embodiments, with reference to FIG. 18, the isolation structure 140 includes a support portion 141 and a shielding portion 142 on a side of the support portion 141 away from the substrate 111, and an orthographic projection of an end of the support portion 141 close to the isolation opening 910 on the substrate 111 is located within an orthographic projection of an end of the shielding portion 142 close to the isolation opening 910 on the substrate 111.

In one embodiment, an etching resistance of the support portion 141 is weaker than an etching resistance of the shielding portion 142.

In one embodiment, a material of the support portion 141 includes aluminum, and/or a material of the shielding portion 142 includes titanium.

In some embodiments, with reference to FIG. 19, the isolation structure 140 further includes a receiving portion 143 between the support portion 141 and the substrate 111.

In one embodiment, an orthographic projection of an end of the receiving portion 143 close to the isolation opening 910 on the substrate 111 is located within the orthographic projection of the end of the shielding portion 142 close to the isolation opening 910 on the substrate 111.

In one embodiment, a material of the receiving portion 143 includes molybdenum.

The present application also provides an electronic device, including a display panel provided in the present application, or a display panel made by a method of manufacturing the display panel provided in the present application. The electronic device may include a device having a display function, e.g., a mobile phone, a tablet, a smart wearable device, a TV, a laptop, a display, etc.

In summary, with the display panel and the electronic device provided in the present application, the connecting portion of the first electrode of the light-emitting device is arranged such that the maximum width in the direction away from the first side is less than the maximum width in the other direction, as such, it is possible to reduce a spacing between the first electrode and a first electrode of a further light-emitting device in the direction away from the first side while the conductive area of the connecting portion is ensured, thereby improving the pixel opening rate of the display panel.

1. A display panel, comprising:
a substrate;
an array functional layer on one side of the substrate; and
a plurality of light-emitting devices located on a side of the array functional layer away from the substrate and spaced apart from each other, each of the light-emitting devices comprising a first electrode, a light-emitting layer and a second electrode which are stacked in a direction away from the substrate;
wherein the array functional layer comprises a routing hole; the first electrode comprises a connecting portion, the connecting portion extending into the routing hole and being electrically connected to a pixel drive circuit in the array functional layer; and an orthographic projection of the connecting portion on the substrate is close to an orthographic projection of a first side of the first electrode on the substrate, and a maximum width of the connecting portion in a direction away from the first side is less than maximum widths of the connecting portion in other directions.

2. The display panel according to claim 1, wherein the orthographic projection of the connecting portion on the substrate comprises at least one of an ellipse, a diamond and a rectangle, and a major axis of the orthographic projection of the connecting portion on the substrate is parallel to the first side.

3. The display panel according to claim 2, wherein a minor axis of the orthographic projection of the connecting portion on the substrate has a length of 2.5 to 4 microns.

4. The display panel according to claim 1, wherein the display panel further comprises an isolation structure on a side of the substrate, the isolation structure enclosing an isolation opening; an orthographic projection of the isolation opening on the substrate is located within an orthographic projection of the first electrode on the substrate, and the orthographic projection of the isolation opening on the substrate is staggered with the orthographic projection of the connecting portion on the substrate; and
the isolation opening exposes at least part of the first electrode of the light-emitting device, and at least part of the light-emitting layer and the second electrode of the light-emitting device is located within the isolation opening.

5. The display panel according to claim 4, wherein at least part of the first electrode of the light-emitting device comprises a body portion and a protrusion that protrudes from a side of the body portion close to a further light-emitting device in a direction away from the body portion; and the orthographic projection of the connecting portion on the substrate is located within an orthographic projection of the protrusion on the substrate.

6. The display panel according to claim 5, wherein the light-emitting devices comprise a first light-emitting device and a second light-emitting device adjacent to each other; and
a first electrode of the first light-emitting device comprises a first body portion and a first protrusion protruding toward the second light-emitting device from a side of the first body portion close to the second light-emitting device; an orthographic projection of the connecting portion corresponding to the first light-emitting device on the substrate is located within an orthographic projection of the first protrusion on the substrate;
a first electrode of the second light-emitting device comprises a second body portion and a second protrusion protruding toward the first light-emitting device from a side of the second body portion close to the first light-emitting device; and an orthographic projection of the connecting portion corresponding to the second light-emitting device on the substrate is located within an orthographic projection of the second protrusion on the substrate.

7. The display panel according to claim 6, wherein a first gap is provided between the first body portion and the second body portion, and the first protrusion and the second protrusion are located in the first gap;
the first light-emitting device and the second light-emitting device are arranged in a first direction; the first protrusion and the second protrusion are staggered in the first direction; and
the first gap has a width of 6 to 15 microns.

8. The display panel according to claim 7, wherein the light-emitting device further comprises a third light-emitting device adjacent to both the first light-emitting device and the second light-emitting device; the third light-emitting device is located on a side of the first light-emitting device and the second light-emitting device in a second direction, the second direction intersecting the first direction;
a first electrode of the third light-emitting device comprises a third body portion and a third protrusion protruding in the second direction from the third body portion toward a direction away from the third body portion; an orthographic projection of the connecting portion corresponding to the third light-emitting device on the substrate is located within an orthographic projection of the third protrusion on the substrate; and
the third protrusion is located on a side of the third body portion close to the first light-emitting device or the second light-emitting device, or the third protrusion is located on a side of the third body portion away from the first light-emitting device or the second light-emitting device.

9. The display panel according to claim 7, wherein the light-emitting device further comprises a third light-emitting device adjacent to both the first light-emitting device and the second light-emitting device; the third light-emitting device is located on a side of the first light-emitting device and the second light-emitting device in a second direction, the second direction intersecting the first direction;
the isolation structure corresponding to the third light-emitting device comprises a first inner recess protruding to a center of the isolation opening corresponding to the third light-emitting device, the first inner recess being located on a side of the isolation opening corresponding to the third light-emitting device in the second direction;
an orthographic projection of the connecting portion corresponding to the third light-emitting device on the substrate at least partially coincides with an orthographic projection of the first inner recess on the substrate; and
the first inner recess is located on a side of the isolation opening corresponding to the third light-emitting device close to the first light-emitting device or the second light-emitting device, or the first inner recess is located on a side of the isolation opening corresponding to the third light-emitting device away from the first light-emitting device or the second light-emitting device.

10. The display panel according to claim 8, wherein orthographic projections of the connecting portion corresponding to the first light-emitting device, the connecting portion corresponding to the second light-emitting device and the connecting portion corresponding to the third light-emitting device on the substrate are on the same straight line.

11. The display panel according to claim 8, wherein the display panel comprises a first pixel column and a second pixel column; in the first pixel column, a plurality of first light-emitting devices and a plurality of second light-emitting devices are alternately arranged in the first direction; in the second pixel column, a plurality of third light-emitting devices are arranged in the first direction;
the first pixel column and the second pixel column are alternately arranged in the second direction; and
one of the first light-emitting devices and one of the second light-emitting devices adjacent to each other in the same first pixel column form a group, and one of the third light-emitting devices is located on a side of the group of the first light-emitting device and the second light-emitting device in the second direction.

12. The display panel according to claim 5, wherein the light-emitting device comprises a first light-emitting device, a second light-emitting device, and a third light-emitting device, the first light-emitting device, the second light-emitting device and the third light-emitting device being arranged in a second direction; the protrusion corresponding to each of the light-emitting devices is located on a side of the body portion in the first direction, the first direction intersecting the second direction; and
orthographic projections of the connecting portions corresponding to the light-emitting devices arranged in the second direction on the substrate are on the same straight line.

13. The display panel according to claim 4, wherein at least part of the isolation structure corresponding to the light-emitting device comprises an inner recess protruding to the center of the corresponding isolation opening, the inner recess being located on a side of the isolation opening close to the other isolation opening; and
an orthographic projection of the connecting portion corresponding to the light-emitting device on the substrate at least partially coincides with an orthographic projection of the inner recess on the substrate.

14. The display panel according to claim 4, wherein the display panel further comprises a pixel defining layer located between the array functional layer and the isolation structure, the pixel defining layer comprising a pixel opening, and an orthographic projection of the pixel opening on the substrate being located within the orthographic projection of the isolation opening on the substrate; and the pixel opening exposes at least part of the first electrode.

15. The display panel according to claim 14, wherein a first spacing is provided between an edge of an orthographic projection of at least part of the isolation opening corresponding to the light-emitting device on the substrate and an edge of an orthographic projection of the pixel opening corresponding to the light-emitting device on the substrate; and
an orthographic projection of the connecting portion corresponding to the light-emitting device on the substrate at least partially coincides with an orthographic projection of the first spacing on the substrate.

16. The display panel according to claim 4, wherein the display panel further comprises an encapsulation unit on a side of the second electrode away from the substrate, the encapsulation unit extending from within the isolation opening to a side of the isolation structure away from the substrate; and
a second gap is provided between at least two adjacent encapsulation units, and the second gap is located on the side of the isolation structure away from the substrate.

17. The display panel according to claim 16, wherein the display panel further comprises a first encapsulation layer and a second encapsulation layer on a side of the encapsulation unit and the isolation structure away from the substrate;
a material of each of the encapsulation unit and the second encapsulation layer comprises an inorganic material; and a material of the first encapsulation layer comprises an organic material.

18. The display panel according to claim 16, wherein the isolation structure comprises a support portion and a shielding portion on a side of the support portion away from the substrate, and an orthographic projection of an end of the support portion close to the isolation opening on the substrate is located within an orthographic projection of an end of the shielding portion close to the isolation opening on the substrate;
an etching resistance of the support portion is weaker than an etching resistance of the shielding portion; and
a material of the support portion comprises aluminum and a material of the shielding portion comprises titanium.

19. The display panel according to claim 18, wherein the isolation structure further comprises a receiving portion between the support portion and the substrate;
an orthographic projection of an end of the receiving portion close to the isolation opening on the substrate is located within an orthographic projection of an end of the shielding portion close to the isolation opening on the substrate; and
a material of the receiving portion comprises molybdenum.

20. An electronic device, comprising a display panel according to claim 1.
